(19) United States
(12) Patent Application Publication
(10) Pub. No.: US 2023/0050067 A1
(43) Pub. Date: Feb. 16, 2023

(54) SEMICONDUCTOR DEVICE

(71) Applicant: FUJI ELECTRIC CO., LTD., Kawasaki-shi (JP)

(72) Inventors: Yoshiaki TOYODA, Matsumoto-city (JP); Hideaki KATAKURA, Matsumoto-city (JP)

(73) Assignee: FUJI ELECTRIC CO., LTD., Kawasaki-shi (JP)

(21) Appl. No.: 17/846,461

(22) Filed: Jun. 22, 2022

(30) Foreign Application Priority Data
Aug. 12, 2021 (JP) 2021-131675

(51) Int. Cl. H01L 27/02

(52) U.S. Cl. CPC H01L 27/0255

(57) ABSTRACT

A semiconductor device includes: a semiconductor base body of a first conductivity type; a high-potential-side terminal connected to the semiconductor base body; a horizontal control circuit element deposited at an upper part of the semiconductor base body; a signal input terminal connected to a control electrode of the control circuit element; a low-potential-side terminal connected to a main electrode region of the control circuit element; an input-side diode connected in a forward direction between the signal input terminal and the semiconductor base body; and a vertical protective element connected between the semiconductor base body and the low-potential-side terminal.

### CROSS-REFERENCE TO RELATED APPLICATION

This application claims benefit of priority under 35 USC 119 based on Japanese Patent Application No. 2021-131675 filed on Aug. 12, 2021, the entire contents of which are incorporated by reference herein.

### BACKGROUND

### 1. Field of the Invention

The present invention relates to a semiconductor device including protective elements for protecting semiconductor elements against external surge such as electrostatic discharge (ESD).

### 2. Description of the Related Art

A high-side power IC is known that includes a vertical power semiconductor element (an output-stage element) and a control circuit for controlling the power semiconductor element integrated (mounted together) on the same semiconductor chip. An example of such a high-side power IC is an onboard power IC called an intelligent power switch (IPS). The control circuit of the high-side power IC has a configuration, as necessary, in which a gate of a control circuit element is connected to a signal input terminal to which an external signal is input from a microcomputer, for example. To avoid breakdown of the gate of the control circuit element derived from external surge applied to the signal input terminal, protective elements such as diodes are added between the signal input terminal and a GND terminal.

When an input voltage required for the signal input terminal is high, horizontal diodes having relatively low breakdown voltage are connected in series at multiple stages, and are used as protective elements to increase the breakdown voltage so as not to fall below the required input voltage. When diodes (diffusion diodes) provided in a silicon substrate are used as the multi-stage diodes, a vertical parasitic bipolar structure of the diodes may cause an error operation. To deal with this, polysilicon diodes without having such a parasitic bipolar structure are used as the multi-stage diodes.

JP 5764254 B, JP 4957686 B, JP 5130843 B, and JP 5214704 B each disclose protective elements for protecting semiconductor elements against external surge.

Polysilicon diodes, when used as the protective elements, are required to have a large area for ensuring a necessary degree of surge immunity, since the polysilicon diodes have less surge immunity than the diffusion diodes per unit area.

### SUMMARY

In view of the foregoing issue, the present invention provides a semiconductor device including protective elements for protecting control circuit elements against external surge.

An aspect of the present invention inheres in a semiconductor device including: a semiconductor base body of a first conductivity type; a high-potential-side terminal connected to the semiconductor base body; a horizontal control circuit element deposited at an upper part of the semiconductor base body; a signal input terminal connected to a control electrode of the control circuit element; a low-potential-side terminal connected to a main electrode region of the control circuit element; an input-side diode connected in a forward direction between the signal input terminal and the semiconductor base body; and a vertical protective element connected between the semiconductor base body and the low-potential-side terminal.

### BRIEF DESCRIPTION OF THE DRAWINGS

FIG. 1 is a circuit diagram of a semiconductor device according to a first embodiment of the present invention;

FIG. 2 is a cross-sectional view of the semiconductor device according to the first embodiment of the present invention;

FIG. 3 is a circuit diagram of a semiconductor device of a comparative example;

FIG. 4 is a cross-sectional view of the semiconductor device of the comparative example;

FIG. 5 is a circuit diagram of a semiconductor device according to a second embodiment of the present invention;

FIG. 6 is a cross-sectional view of the semiconductor device according to the second embodiment of the present invention;

FIG. 7 is a graph showing a relationship between an applied voltage and a current in a protective element in each of the semiconductor device according to the second embodiment and the semiconductor device of the comparative example;

FIG. 8 is a circuit diagram of a semiconductor device according to a third embodiment of the present invention;

FIG. 9 is another circuit diagram of the semiconductor device according to the third embodiment of the present invention; and

FIG. 10 is still another circuit diagram of the semiconductor device according to the third embodiment of the present invention.

### DETAILED DESCRIPTION

With reference to the Drawings, embodiments of the present invention will be described below. In the Drawings, the same or similar elements are indicated by the same or similar reference numerals. The Drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

In the embodiment, a “first main electrode region” and a “second main electrode region” are a main electrode region of a semiconductor element, in which a main current flows in or out. The first main electrode region is assigned to a semiconductor region which is an emitter region or a collector region in an insulated-gate bipolar transistor (IGBT). The first main electrode region is assigned to a semiconductor region which is a source region or a drain region in a field-effect transistor (FET) or a static induction transistor (SIT). The first main electrode region is assigned to a semiconductor region which is an anode region or a cathode region in a static induction (SI) thyristor or a gate turn-off (GTO) thyristor. The second main electrode region is assigned to a semiconductor region which is not assigned as the first main electrode region and will be the emitter region or the collector region in the IGBT, the source region or the drain region in the FET or the SIT, and the anode region or the cathode region in the SI thyristor or the GTO thyristor.

That is, when the first main electrode region is the source region, the second main electrode region means the drain region. When the first main electrode region is the emitter region, the second main electrode region means the collector region. When the first main electrode region is the anode region, the second main electrode region means the cathode region. A “main electrode region” is described in the Specification, the main electrode region comprehensively means any one of the first main electrode region and the second main electrode region.

Further, definitions of directions such as an up-and-down direction such as “top surface” or “bottom surface” or right-and-left direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

Further, in the following description, there is exemplified a case where a first conductivity type is an n-type and a second conductivity type is a p-type. However, the relationship of the conductivity types may be inverted to set the first conductivity type to the p-type and the second conductivity type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

### First Embodiment

A semiconductor device according to a first embodiment includes a signal input terminal 101 to which an external signal is input, a high-potential-side terminal (a VCC terminal) 102 to which a first potential is applied, and a low-potential-side terminal (a GND terminal) 103 to which a second potential lower than the first potential is applied. A VCC potential is applied to the high-potential-side terminal 102 as a first potential that is a power supply potential of about 15 volts of a high-side power IC, for example. A GND potential is applied to the low-potential-side terminal 103 as a second potential that is a ground potential, for example.

The semiconductor device according to the first embodiment includes an internal power supply circuit 100 and a control circuit 300. The internal power supply circuit 100 is connected to the high-potential-side terminal 102. The internal power supply circuit 100 includes a plurality of control circuit elements (not illustrated). The VCC potential is applied to a predetermined part in the internal power supply circuit 100 via the high-potential-side terminal 102 so that the internal power supply circuit 100 exhibits necessary circuit operations.

The control circuit 300 includes a horizontal control circuit element T1. The control circuit element T1 is a MOS transistor, for example. A first main electrode (a drain) of the control circuit element T1 is connected to the internal power supply circuit 100 directly or via another control circuit element (not illustrated). A third potential (about 5 volts, for example) lower than the first potential (the VCC potential) and higher than the second potential (the GND potential) is applied to the drain of the control circuit element T1 via the internal power supply circuit 100. A second main electrode (a source) of the control circuit element T1 is connected to the low-potential-side terminal 103. A control electrode (a gate) of the control circuit element T1 is connected to the signal input terminal 101.

The semiconductor device according to the first embodiment includes protective elements that are an input-side diode D1 and a vertical protective element (a vertical protective diode) D2 for protecting the control circuit element T1 against the external surge applied to the signal input terminal 101. The input-side diode D1 is a forward-direction diode connected between the signal input terminal 101 and the high-potential-side terminal 102. An anode of the input-side diode D1 is connected to the signal input terminal 101 and the gate of the control circuit element T1. A cathode of the input-side diode D1 is connected to the high-potential-side terminal 102 and the internal power supply circuit 100.

The vertical protective diode D2 is a diode connected in the reverse direction between the high-potential-side terminal 102 and the low-potential-side terminal 103. A cathode of the vertical protective diode D2 is connected to the cathode of the input-side diode D1, the high-potential-side terminal 102, and the internal power supply circuit 100. An anode of the vertical protective diode D2 is connected to the low-potential-side terminal 103 and the source of the control circuit element T1.

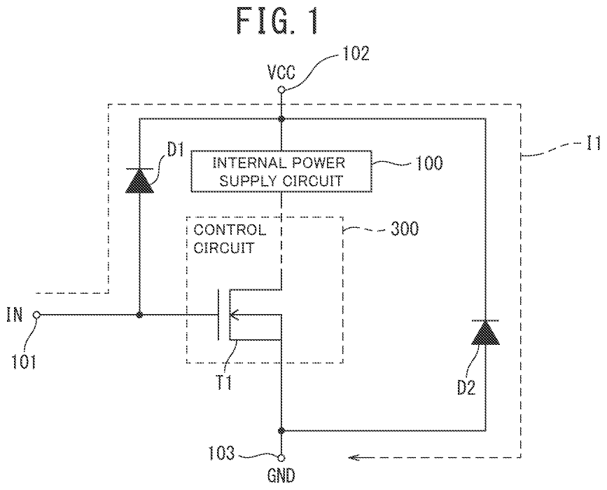

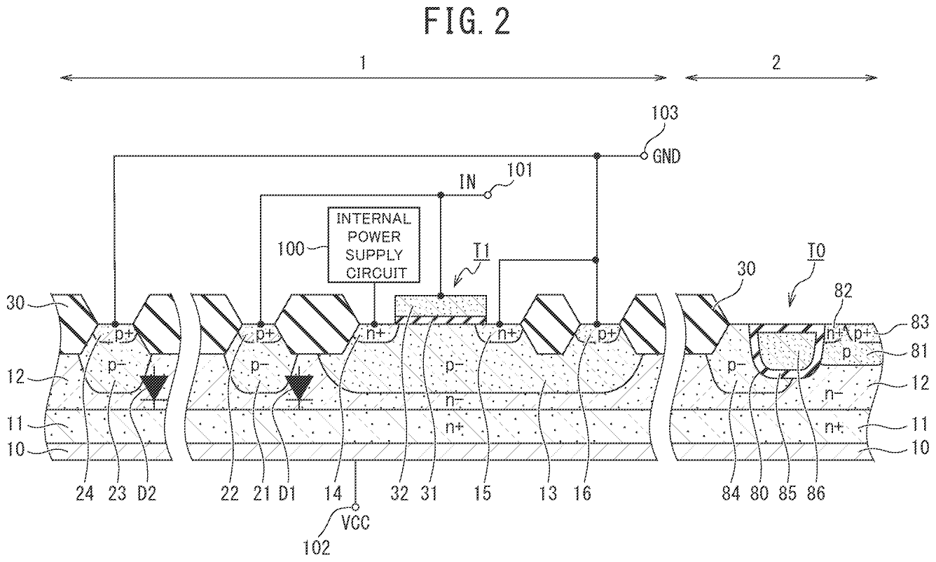

FIG. 2 is a cross-sectional view of a semiconductor integrated circuit to which the semiconductor device according to the first embodiment is applied. As illustrated in FIG. 2, the semiconductor device (the semiconductor integrated circuit) according to the first embodiment is a high-side power IC in which a control circuit unit 1 and an output unit 2 are monolithically integrated on the same semiconductor chip. The control circuit unit 1 illustrated on the left side in FIG. 2 corresponds to the circuit diagram of the semiconductor device according to the first embodiment illustrated in FIG. 1. The output unit 2 illustrated on the right side in FIG. 2 includes an output-stage element T0 that is a power semiconductor element controlled by the control circuit unit 1.

As illustrated in FIG. 2, the semiconductor device according to the first embodiment includes a semiconductor base body (11, 12) of a first conductivity type (n-type). The semiconductor base body (11, 12) includes a low specific resistance layer 11 of n⁺-type, and a high specific resistance layer 12 of n⁻-type deposited on the top surface of the low specific resistance layer 11 and having a lower impurity concentration and higher specific resistance than the low specific resistance layer 11.

The low specific resistance layer 11 is a semiconductor substrate (a Si wafer) made from silicon (Si), for example. The high specific resistance layer 12 is an epitaxially-grown layer made from Si and epitaxially grown on the low specific resistance layer 11. The semiconductor base body (11, 12) may be implemented such that the low specific resistance layer 11 of an impurity-doped layer of n⁺-type is formed by ion implantation or thermal diffusion on the bottom surface of the n⁻-type semiconductor substrate (the Si wafer) that is the high specific resistance layer 12.

The low specific resistance layer 11, when used as the n⁺-type semiconductor substrate, has an impurity concentration in a range of about 2×10¹⁸ cm⁻³ to 1×10¹⁹ cm⁻³, for example. In this case, an impurity concentration of the high specific resistance layer 12 can be set within a range of about 1×10¹² cm⁻³ to 1×10¹⁶ cm⁻³, and is herein set in a range of about 1×10¹⁵ cm⁻³ to 1×10¹⁶ cm⁻³, for example. When the low specific resistance layer 11 of the n⁺-type impurity-doped layer is formed on the bottom surface of the high specific resistance layer 12 of the n⁻-type semiconductor substrate, the impurity concentration of the low specific resistance layer 11 can be set in a range of about 5×10¹⁸ cm⁻³ to 1×10²¹ cm⁻³. The impurity concentration of the low specific resistance layer 11 is not necessarily constant, and can have an impurity profile increased to an impurity concentration as high as about 1×10²¹ cm⁻³ at the bottom surface of the low specific resistance layer 11. The low specific resistance layer 11 may have a composite structure including an upper layer of about 5×10¹⁸ cm⁻³ to 2×10¹⁹ cm⁻³ and a lower layer of about 3×10¹⁹ cm⁻³ to 1×10²¹ cm⁻³, for example.

The semiconductor base body (11, 12) is illustrated below with a case of being made from a semiconductor material such as Si as a base material, but the base material is not limited to Si. The semiconductor base body (11, 12) may also use a semiconductor (wide band-gap semiconductor) material having a wider band gap than Si, such as silicon carbide (SiC), gallium nitride (GaN), diamond, and aluminum nitride (AlN).

A bottom-surface electrode (a rear-surface electrode) 10 is deposited on the bottom surface of the low specific resistance layer 11. The high-potential-side terminal 102 is electrically connected to the bottom-surface electrode 10. The VCC potential is applied to the bottom-surface electrode 10 via the high-potential-side terminal 102 so that the potential of the semiconductor base body (11, 12) is fixed to the VCC potential.

The control circuit unit 1 illustrated on the left side in FIG. 2 includes the control circuit element T1, the input-side diode D1, the vertical protective diode D2, and the internal power supply circuit 100. Although not illustrated in FIG. 2, the internal power supply circuit 100 includes a plurality of control circuit elements provided on the semiconductor base body (11, 12). The control circuit element T1 is a horizontal n-channel MOSFET, for example. The control circuit element T1 is provided in a well region 13 of p⁻-type deposited at an upper part of the high specific resistance layer 12. The control circuit element T1 includes a first main electrode region (a drain region) 14 of n⁺-type and a second main electrode region (a source region) 15 of n⁺-type selectively deposited at upper parts of the well region 13 separately from each other. The control circuit element T1 also includes a base contact region 16 of p⁺-type having a higher impurity concentration than the well region 13 and selectively deposited at an upper part of the well region 13 separately from the drain region 14 and the source region 15.

The control circuit element T1 includes a planar-type control electrode structure (31, 32) deposited on the well region 13. The control electrode structure (31, 32) includes a gate insulating film 31 deposited on the well region 13 interposed between the drain region 14 and the source region 15, and a gate electrode 32 further deposited on the gate insulating film 31. The signal input terminal 101 is electrically connected to the gate electrode 32. The gate electrode 32 electrostatically controls a surface potential of the well region 13 via the gate insulating film 31, so as to form an inversion channel on the surface layer of the well region 13.

The gate insulating film 31 as used herein can be a silicon oxide film (a SiO₂ film), for example, and other examples other than the SiO₂ film include a silicon oxynitride (SiON) film, a strontium oxide (SrO) film, a silicon nitride (Si₃N₄) film, and an aluminum oxide (Al₂O₃) film. Still other examples include a magnesium oxide (MgO) film, an yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film. Further, two or more of these single films may be chosen and stacked on one another so as to be used as a composite film.

The material used for the gate electrode 32 may be polysilicon (doped polysilicon) with which n-type impurity ions or p-type impurity ions are heavily doped, for example. Other examples other than the doped polysilicon (DOPOS) include a refractory metal such as tungsten (W), molybdenum (Mo), and titanium (Ti), and silicide of the refractory metal and the polysilicon. The material used for the gate electrode 32 may also be polycide which is a composite film of the polysilicon and the silicide of the refractory metal.

FIG. 2 schematically illustrates circuit symbols of the input-side diode D1 and the vertical protective diode D2. The input-side diode D1 is implemented by a p-n junction of a cathode region that is a part of the high specific resistance layer 12 and an anode region 21 of p⁻-type provided at an upper part of the high specific resistance layer 12. An anode contact region 22 of p⁺-type having a higher impurity concentration than the anode region 21 is deposited at an upper part of the anode region 21. The signal input terminal 101 and the gate electrode 32 of the control circuit element T1 are electrically connected to the anode contact region 22.

While FIG. 2 illustrates the case in which the input-side diode D1 is a diffusion diode formed in the semiconductor base body (11, 12), the input-side diode D1 is not limited to the diffusion diode. The input-side diode D1 may be a horizontal polysilicon diode provided on an insulating film 30 of the semiconductor base body (11, 12), for example.

The vertical protective diode D2 is implemented by a p-n junction of the cathode region that is a part of the high specific resistance layer 12 and an anode region 23 of p⁻-type deposited at an upper part of the high specific resistance layer 12. An anode contact region 24 of p⁺-type having a higher impurity concentration than the anode region 23 is deposited at an upper part of the anode region 23. The low-potential-side terminal 103, and the source region 15 and the base contact region 16 of the control circuit element T1 are electrically connected to the anode contact region 24.

The anode region 21 implementing the input-side diode D1 may have the same depth and the same impurity concentration as the anode region 23 implementing the vertical protective diode D2, and the anode region 21 and the anode region 23 may be formed in the same process. While FIG. 2 illustrates the case in which the width of the anode region 23 implementing the vertical protective diode D2 is the same as the width of the anode region 21 implementing the input-side diode D1, the width of the anode region 23 implementing the vertical protective diode D2 may be greater than the width of the anode region 21 implementing the input-side diode D1, and may be determined as appropriate depending on a surge immunity required.

The insulating film 30 is deposited on the top surface of the high specific resistance layer 12. The insulating film 30 is a field oxide film such as a film of local oxidation of silicon (LOCOS) selectively (locally) formed by a method of LOCOS, for example. The insulating film 30 is not necessarily the field oxide film, and may be any other insulating film. The insulating film 30 is selectively provided so as to expose the drain region 14, the source region 15, the base contact region 16, the anode contact region 22, the anode contact region 24, and the like.

The output unit 2 illustrated on the right side of FIG. 2 includes the vertical output-stage element T0. The output-stage element T0 is a trench-gate n-channel MOSFET. The output-stage element T0 causes a part of the low specific resistance layer 11 to serve as a first main electrode region (a drain region), and causes a part of the high specific resistance layer 12 located over the drain region to serve as a drift layer.

A body region (a base region) 81 of p-type is deposited at an upper part of the high specific resistance layer 12. A second main electrode region (a source region) 82 of n⁺-type is selectively deposited at an upper part of the body region 81. A base contact region 83 of p⁺-type having a higher impurity concentration than the body region 81 is selectively deposited in contact with the source region 82 at an upper part of the body region 81. An output terminal (not illustrated) is electrically connected to the source region 82 and the base contact region 83.

A trench 80 is provided on the top surface side of the semiconductor base body (11, 12). The trench 80 has a greater depth than the body region 81, while at least a part of the side surface of the trench 80 is in contact with the body region 81. A well region 84 of p⁻-type is provided in contact with the trench 80 at an upper part of the high specific resistance layer 12.

A gate insulating film 85 is provided inside and along the inner surface of the trench 80. A gate electrode 86 is buried in the trench 80 via the gate insulating film 85 so as to implement a trench-type control electrode structure (85, 86). The gate electrode 86 electrostatically controls a surface potential of the body region 81 at a part on the side surface side of the trench 80 via the gate insulating film 85, so as to form an inversion channel in the body region 81 on the side surface side of the trench 80. A main current flows via the inversion channel in the output-stage element T0 between the source region 82 on the top surface side and the drain region implemented by a part of the low specific resistance layer 11 on the bottom surface side opposed to the source region 82.

The operations of the protective elements of the semiconductor device according to the first embodiment are described below. When an external surge is applied to the signal input terminal 101 illustrated in FIG. 1, a potential of the semiconductor base body (11, 12) connected to the high-potential-side terminal 102 increases via the input-side diode D1. When the vertical protective diode D2 yields so that the potential increases to a level at which the reverse-direction current flows, the surge current I1 flows the input-side diode D1, the vertical protective diode D2, and the low-potential-side terminal 103 so as to be absorbed thereto.

### Comparative Example

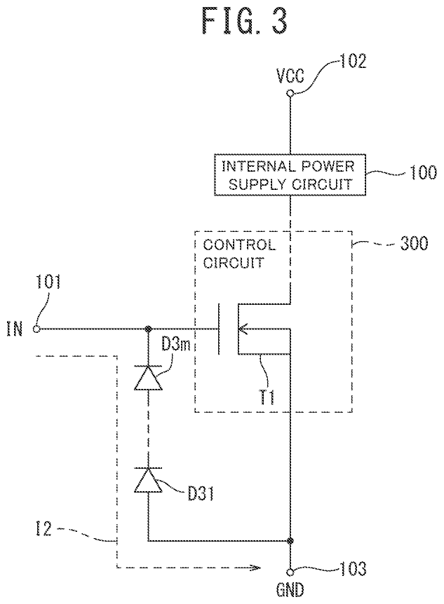

A semiconductor device of a comparative example is described below. The semiconductor device of the comparative example has the same structure as the semiconductor device according to the first embodiment illustrated in FIG. 1 in including the signal input terminal 101, the high-potential-side terminal (the VCC terminal) 102, and the low-potential-side terminal (the GND terminal) 103, and further including the internal power supply circuit 100 and the control circuit element T1, as illustrated in FIG. 3. The semiconductor device of the comparative example differs from the semiconductor device according to the first embodiment in including a plurality of polysilicon diodes D31, . . . , and D3m (m is an integer of two or greater) provided at multiple stages connected in series in the reverse direction between the signal input terminal 101 and the high-potential-side terminal 103. The plural polysilicon diodes D31, . . . , and D3m are provided at two to three stages, for example.

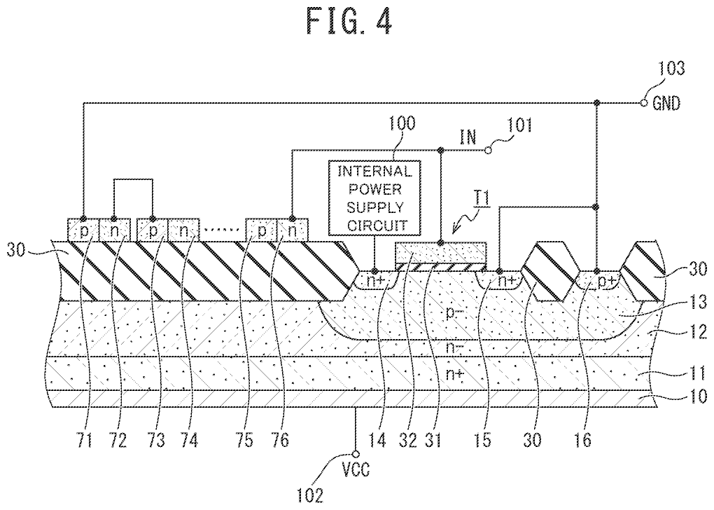

FIG. 4 is a cross-sectional view of the semiconductor device of the comparative example. FIG. 4 omits the illustration of the output unit 2 illustrated in FIG. 2. As illustrated in FIG. 4, the semiconductor device of the comparative example includes a semiconductor layer 71 of p-type and a semiconductor layer 72 of n-type provided in contact with each other on the insulating film 30. The semiconductor device of the comparative example further includes a semiconductor layer 73 of p-type and a semiconductor layer 74 of n-type provided in contact with each other on the insulating film 30 separately from the p-type semiconductor layer 71 and the n-type semiconductor layer 72. The semiconductor device of the comparative example further includes a semiconductor layer 75 of p-type and a semiconductor layer 76 of n-type provided in contact with each other on the insulating film 30 separately from the respective p-type semiconductor layers 71 and 73 and the respective n-type semiconductor layers 72 and 74.

The p-type semiconductor layers 71, 73, and 75 and the n-type semiconductor layers 72, 74, and 76 are each made from polysilicon with which impurity ions are heavily doped. The p-n junction of the p-type semiconductor layer 71 and the n-type semiconductor layer 72 implements the polysilicon diode D31 illustrated in FIG. 3. The p-n junction of the p-type semiconductor layer 75 and the n-type semiconductor layer 76 implements the polysilicon diode D3m illustrated in FIG. 3.

The semiconductor device of the comparative example uses the polysilicon diodes D31, . . . , and D3m as protective elements. The polysilicon diodes D31, . . . , and D3m, however, have a lower surge immunity per unit area than diffusion diodes, and thus require a larger area for ensuring a necessary surge immunity.

In contrast, the semiconductor device according to the first embodiment uses the input-side diode D1 and the vertical protective diode D2 as the protective elements. The input-side diode D1 and the vertical protective diode D2 ensure a higher breakdown current than the polysilicon diodes D31, . . . , and D3m when having the same area, and thus can exhibit substantially the same level of the surge current absorption capability (the surge immunity) with a smaller area than the polysilicon diodes D31, . . . , and D3m, so as to achieve a reduction in area of the protective elements accordingly. In addition, the use of the input-side diode D1 and the vertical protective diode D2 can enhance the radiation performance more than the case of using the polysilicon diodes D31, . . . , and D3m.

### Second Embodiment

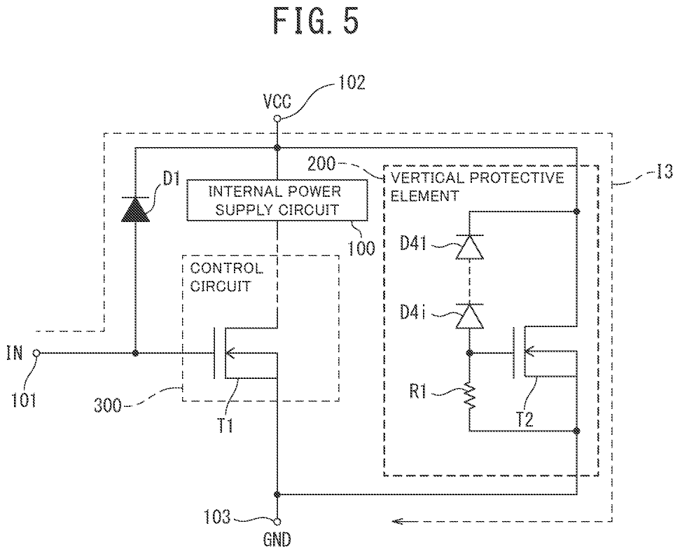

A semiconductor device according to a second embodiment has the same structure as the semiconductor device according to the first embodiment illustrated in FIG. 1 in including the signal input terminal 101, the high-potential-side terminal (the VCC terminal) 102, and the low-potential-side terminal (the GND terminal) 103, and further including the internal power supply circuit 100 and the control circuit element T1, as illustrated in FIG. 5. The semiconductor device according to the second embodiment differs from the semiconductor device according to the first embodiment in using a vertical protective element 200 that is an active clamp protective element.

The vertical protective element 200 includes a vertical MOS transistor T2, a plurality of horizontal diodes (polysilicon diodes) D41, . . . , and D4i (i is an integer of two or greater) provided at multiple stages connected in series, and a resistor (a polysilicon resistor) R1. The plural horizontal diodes D41, . . . , and D4i are provided at two to three stages, for example. The horizontal diodes D41, . . . , and D4i may be provided at a single stage.

A first main electrode (a drain) of the MOS transistor T2 is connected to the cathode of the input-side diode D1, the high-potential-side terminal 102, and the internal power supply circuit 100. A second main electrode (a source) of the MOS transistor T2 is connected to the low-potential-side terminal 103 and the source of the control circuit element T1.

A cathode of the horizontal diode D41 located at one end of the plural horizontal diodes D41, . . . , and D4i provided at the multiple stages is connected to the drain of the MOS transistor T2, the cathode of the input-side diode D1, the high-potential-side terminal 102, and the internal power supply circuit 100. An anode of the horizontal diode D4i located at the other end of the plural horizontal diodes D41, . . . , and D4i provided at the multiple stages is connected to a gate of the MOS transistor T2 and one end of the resistor R1. The other end of the resistor R1 is connected to a source of the MOS transistor T2, the low-potential-side terminal 103, and the source of the control circuit element T1.

An operating voltage of the vertical protective element 200 serving as an active clamp protective element is determined depending on breakdown voltage of the horizontal diodes D41, . . . , and D4i, a divided voltage ratio of operating resistance of the horizontal diodes D41, . . . , and D4i and the resistor R1, a threshold voltage of the MOS transistor T2, and the like, and can be adjusted by the number of the stages of the horizontal diodes D41, . . . , and D4i provided, for example.

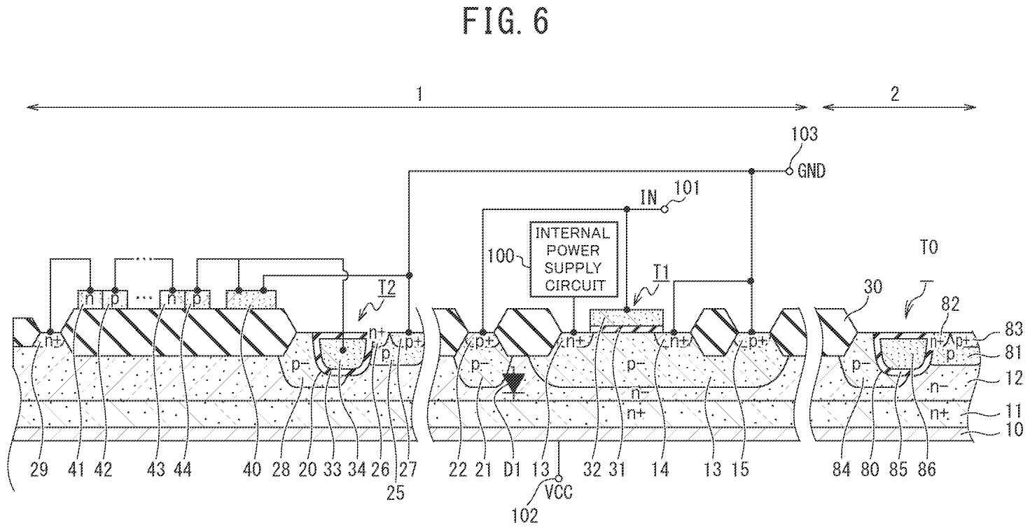

FIG. 6 is a cross-sectional view of a semiconductor integrated circuit to which the semiconductor device according to the second embodiment is applied. The semiconductor device (the semiconductor integrated circuit) according to the second embodiment is a high-side power IC in which the control circuit unit 1 and the output unit 2 are monolithically integrated on the same semiconductor chip, as in the case of the semiconductor device according to the first embodiment. The control circuit unit 1 illustrated on the left side of FIG. 6 corresponds to the circuit diagram of the semiconductor device according to the second embodiment illustrated in FIG. 5. The output unit 2 illustrated on the right side of FIG. 6 includes the output-stage element T0 that is a power semiconductor element controlled by the control circuit unit 1.

The MOS transistor T2 in the control circuit unit 1 illustrated on the left side of FIG. 6 is implemented by a trench-gate n-channel MOSFET, for example. A part of the low specific resistance layer 11 serves as the first main electrode region (the drain region) of the MOS transistor T2, and a part of the high specific resistance layer 12 located over the drain region serves as a drift layer.

A body region (a base region) 25 of p-type is deposited at an upper part of the high specific resistance layer 12. A second main electrode region (a source region) 26 of n⁺-type is selectively deposited at an upper part of the body region 25. A base contact region 27 of p⁺-type having a higher impurity concentration than the body region 25 is selectively deposited in contact with the source region 26 at an upper part of the body region 25. The low-potential-side terminal 103 is electrically connected to the source region 26 and the base contact region 27.

A trench 20 is provided on the top surface side of the semiconductor base body (11, 12). The trench 20 has a greater depth than the body region 25, while at least a part of the side surface of the trench 20 is in contact with the body region 25. A well region 28 of p⁻-type is provided in contact with the trench 20 at an upper part of the high specific resistance layer 12.

A gate insulating film 33 is provided inside and along the inner surface of the trench 20. A gate electrode 34 is buried in the trench 20 via the gate insulating film 33 so as to implement a trench-type control electrode structure (33, 34). The gate electrode 34 electrostatically controls a surface potential of the body region 25 at a part on the side surface side of the trench 20 via the gate insulating film 33, so as to form an inversion channel in the body region 25 on the side surface side of the trench 20.

The MOS transistor T2 has the same structure as the output-stage element T0, and can be formed by the same process as the output-stage element T0. The control electrode structure (33, 34) of the MOS transistor T2 may be the same as the control electrode structure (85, 86) of the output-stage element T0. The body region 25 of the MOS transistor T2 may have the same depth and the same impurity concentration as the body region 81 of the output-stage element T0. The source region 26 of the MOS transistor T2 may have the same depth and the same impurity concentration as the source region 82 of the output-stage element T0. The base contact region 27 of the MOS transistor T2 may have the same depth and the same impurity concentration as the base contact region 83 of the output-stage element T0.

A semiconductor layer 41 of n-type and a semiconductor layer 42 of p-type are provided in contact with each other on the insulating film 30. The n-type semiconductor layer 41 is electrically connected to a substrate contact region 29 of n⁺-type deposited at an upper part of the high specific resistance layer 12 and having a higher impurity concentration than the high specific resistance layer 12. A semiconductor layer 43 of n-type and a semiconductor layer 44 of p-type are provided in contact with each other on the insulating film 30 separately from the n-type semiconductor layer 41 and the p-type semiconductor layer 42. The p-type semiconductor layer 44 is electrically connected to the gate electrode 34 of the MOS transistor T2.

A resistance layer 40 is deposited on the insulating film 30 separately from the respective n-type semiconductor layers 41 and 43 and the respective p-type semiconductor layers 42 and 44. The p-type semiconductor layer 44 and the gate electrode 34 of the MOS transistor T2 are electrically connected to one end of the resistance layer 40. The low-potential-side terminal 103, the source region 26 of the MOS transistor T2, and the base contact region 27 are electrically connected to the other end of the resistance layer 40.

The n-type semiconductor layers 41 and 43, the p-type semiconductor layers 42 and 44, and the resistance layer 40 are each made from polysilicon with which impurity ions are heavily doped. The p-n junction of the n-type semiconductor layer 41 and the p-type semiconductor layer 42 implements the horizontal diode D41 illustrated in FIG. 5. The p-n junction of the n-type semiconductor layer 43 and the p-type semiconductor layer 44 implements the horizontal diode D4i illustrated in FIG. 5. The resistance layer 40 corresponds to the resistor R1 illustrated in FIG. 5. The other configurations of the semiconductor device according to the second embodiment are substantially the same as those of the semiconductor device according to the first embodiment, and overlapping explanations are not repeated below.

The operations of the protective elements of the semiconductor device according to the second embodiment are described below. When an external surge is applied to the signal input terminal 101 illustrated in FIG. 5, the surge voltage increases the potential of the semiconductor base body (11, 12) via the input-side diode D1. When the potential of the semiconductor base body (11, 12) increases, the horizontal diodes D41, . . . , and D4i yield so as to cause a part of the surge current to flow through the path of the horizontal diodes D41, . . . , and D4i and the resistor R1. This current rises up the potential of the gate of the MOS transistor T2 to lead to a predetermined threshold voltage or greater, so that the MOS transistor T2 is turned ON. This leads the surge current I3 to flow through the path sequentially via the input-side diode D1, the semiconductor base body (11, 12) connected to the high-potential-side terminal 102, the MOS transistor T2 (a part of the current flows through the resistor R1), and the low-potential-side terminal 103 so as to be absorbed thereto, as indicated by the broken line in FIG. 5.

The semiconductor device according to the second embodiment uses the input-side diode D1 and the vertical protective element 200 as the protective elements, so as to ensure a higher breakdown current than the polysilicon diodes D31, . . . , and D3m of the semiconductor device of the comparative example as illustrated in FIG. 3 when having the same area, and thus can exhibit substantially the same level of the surge current absorption capability (the surge immunity) with a smaller area than the polysilicon diodes D31, . . . , and D3m, achieving a reduction in area of the protective elements accordingly. In addition, the use of the input-side diode D1 and the vertical protective element 200 can enhance the radiation performance more than the case of using the polysilicon diodes D31, . . . , and D3m.

In addition, since the vertical protective element 200 is the active clamp protective element, regulating the number of the stages of the horizontal diodes D41, . . . , and D4i can facilitate the adjustment of the surge immunity of the vertical protective element 200. Further, the MOS transistor T2 of the vertical protective element 200 having the same structure as the output-stage element T0 can be formed in the same process as the output-stage element T0, so as to avoid an increase in the number of steps for forming the vertical protective element 200 accordingly.

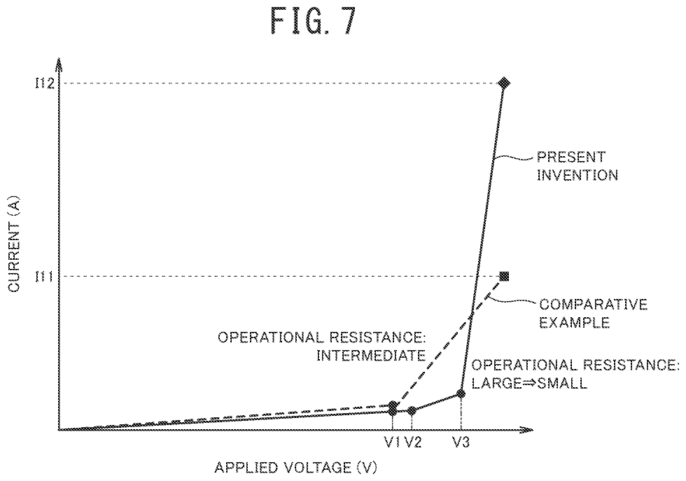

FIG. 7 shows a relationship between the applied voltage and the current in the protective element in each of the semiconductor device according to the second embodiment and the semiconductor device of the comparative example. FIG. 7 indicates the case of the semiconductor device according to the second embodiment by the solid line, and indicates the case of the semiconductor device of the comparative example by the broken line. The applied voltage V1 on the axis of abscissas in FIG. 7 is a breakdown voltage of the polysilicon diodes D31, . . . , and D3m in the semiconductor device of the comparative example. The applied voltage V2 is a sum of a forward voltage of the input-side diode D1 and a breakdown voltage of the horizontal diodes D41, . . . , and D4i in the semiconductor device according to the second embodiment. The applied voltage V3 is an active clamp start voltage of the vertical protective element 200 in the semiconductor device according to the second embodiment (a sum of the forward voltage of the input-side diode D1, the breakdown voltage of the horizontal diodes D41, . . . , and D4i, and a threshold voltage of the MOS transistor T2 (a voltage when turned ON)). The current I11 on the axis of ordinates in FIG. 7 is a breakdown current of the polysilicon diodes D31, . . . , and D3m in the semiconductor device of the comparative example. The current I12 is a breakdown current of the MOS transistor T2 in the semiconductor device according to the second embodiment.

As indicated by the broken line in FIG. 7, the operational resistance from the point at which the polysilicon diodes D31, . . . , and D3m yield to the point at which the polysilicon diodes D31, . . . , and D3m are destroyed in the semiconductor device of the comparative example is the intermediate level. In contrast, as indicated by the solid line in FIG. 7, the operational resistance from the point at which the polysilicon diodes D41, . . . , and D4i yield to the point at which the MOS transistor T2 is turned ON in the semiconductor device according to the second embodiment is greater than the operational resistance in the semiconductor device of the comparative example, and is led to be smaller than the operational resistance in the semiconductor device of the comparative example once the MOS transistor T2 is turned ON. In addition, the breakdown current I12 of the MOS transistor T2 is greater than the breakdown current I11 of the polysilicon diodes D31, . . . , and D3m when having the same area. The semiconductor device according to the second embodiment thus can have a smaller size than the semiconductor device of the comparative example, while achieving the same level of the surge immunity.

For example, the semiconductor device according to the second embodiment can reduce the area of the protective elements by about 50%, as compared with the semiconductor device of the comparative example in the case of having the polysilicon diodes D31, . . . , and D3m provided at three stages.

### Third Embodiment

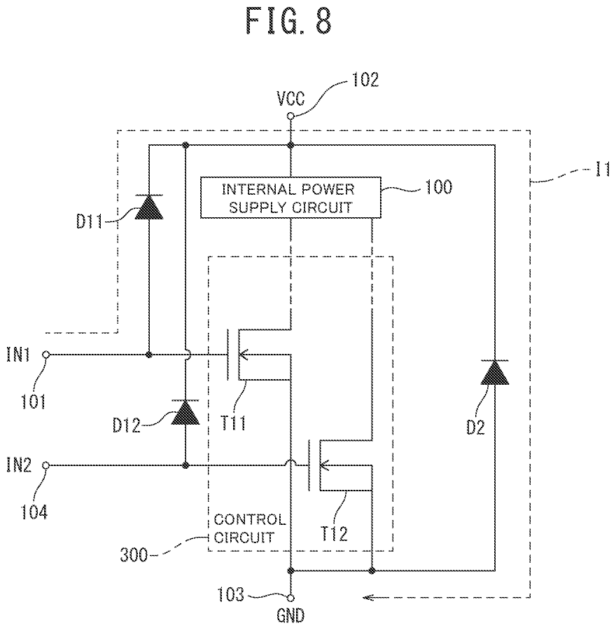

A semiconductor device according to a third embodiment has the same structure as the semiconductor device according to the first embodiment illustrated in FIG. 1 in including the signal input terminal 101, the high-potential-side terminal (the VCC terminal) 102, and the low-potential-side terminal (the GND terminal) 103, and further including the internal power supply circuit 100, as illustrated in FIG. 8. The semiconductor device according to the third embodiment differs from the semiconductor device according to the first embodiment in including a plurality of horizontal control circuit elements T11 and T12 in the control circuit 300 as targets to be protected. The plural control circuit elements T11 and T12 have a structure similar to that of the control circuit element T1 illustrated in FIG. 1.

A first main electrode (a drain) of the control circuit element T11 is connected to the internal power supply circuit 100 directly or via another control circuit element (not illustrated). A second main electrode (a source) of the control circuit element T11 is connected to the low-potential-side terminal 103. A control electrode (a gate) of the control circuit element T11 is connected to the signal input terminal 101. An external signal IN1 is applied to the gate of the control circuit element T11 via the signal input terminal 101.

A first main electrode (a drain) of the control circuit element T12 is connected to the internal power supply circuit 100 directly or via another control circuit element (not illustrated). A second main electrode (a source) of the control circuit element T12 is connected to the low-potential-side terminal 103. A control electrode (a gate) of the control circuit element T12 is connected to the signal input terminal 104. An external signal IN2 different from the external signal IN1 is applied to the gate of the control circuit element T12 via the signal input terminal 104.

An anode of an input-side diode D11 is connected to the signal input terminal 101 and the gate of the control circuit element T11. An anode of an input-side diode D12 is connected to the signal input terminal 104 and the gate of the control circuit element T12. The cathodes of the input-side diodes D11 and D12 are commonly connected to the cathode of the vertical protective element (the vertical protective diode) D2. The other configurations of the semiconductor device according to the third embodiment are substantially the same as those of the semiconductor device according to the first embodiment, and overlapping explanations are not repeated below.

The semiconductor device according to the third embodiment, which includes the plural control circuit elements T11 and T12 as targets to be protected, can use the common vertical protective diode D2. This can reduce the entire size of the protective element as compared with the case in which the polysilicon diodes provided at multiple stages are connected in the reverse direction to the gate of each of the control circuit elements T11 and T12.

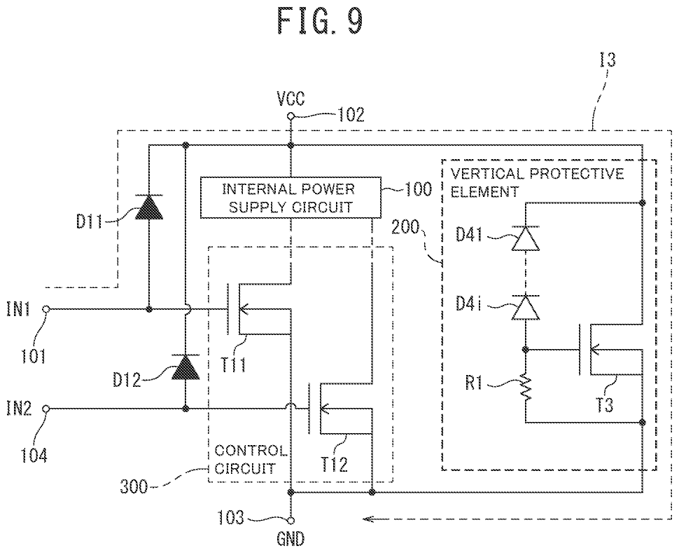

The semiconductor device according to the third embodiment may use the vertical protective element 200, which is the active clamp protective element, instead of the vertical protective diode D2, as illustrated in FIG. 9. The configuration of the vertical protective element 200 is substantially the same as that in the semiconductor device according to the second embodiment, and overlapping explanations are not repeated below.

While FIG. 8 and FIG. 9 each illustrate the case of using the two control circuit elements T11 and T12 as targets to be protected, three or more of control circuit elements may be included as targets to be protected. In such a case, the anodes of the input-side diodes can be connected to the respective control circuit elements, and the vertical protective diode D2 or the vertical protective element 200 that is the active clamp protective element can be commonly connected to the cathodes of the respective input-side diodes.

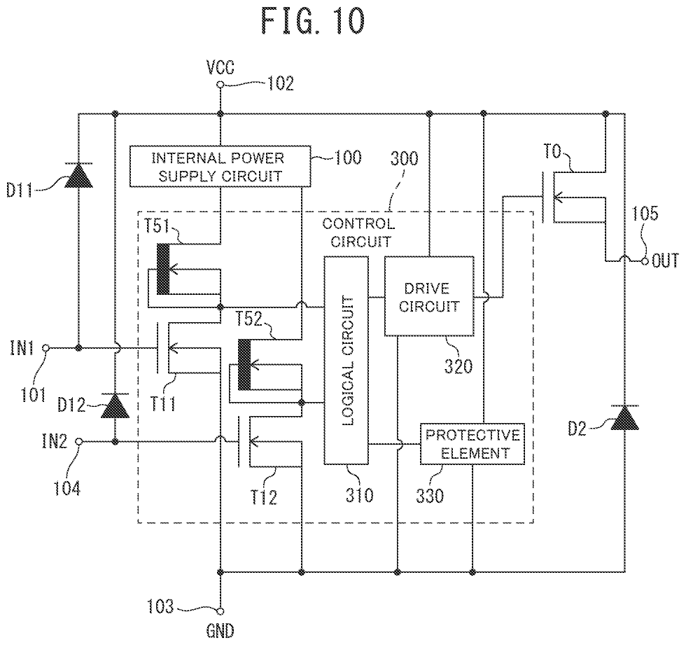

FIG. 10 is a diagram illustrating a specific example of the control circuit 300 illustrated in FIG. 8. The control circuit 300 includes a depletion MOS T51, in which a gate and a source are connected, serving as a load resistance for signal amplification provided between the control circuit element T11 and the internal power supply circuit 100. The gate and the source of the depletion MOS T51 are connected to the drain of the control circuit element T11, and a drain of the depletion MOS T51 is connected to the internal power supply circuit 100. Similarly, a depletion MOS T52, in which a gate and a source are connected, is provided between the control circuit element T12 and the internal power supply circuit 100. The gate and the source of the depletion MOS T52 are connected to the drain of the control circuit element T12, and a drain of the depletion MOS T52 is connected to the internal power supply circuit 100.

The gate and the source of the depletion MOS T51 and the drain of the control circuit element T11 are connected to a logical circuit 310. The gate and the source of the depletion MOS T52 and the drain of the control circuit element T12 are connected to the logical circuit 310. A drive circuit 320 and a protective circuit 330 are connected to the logical circuit 310. The drive circuit 320 is connected to the high-potential-side terminal 102 and the low-potential-side terminal 103. The drive circuit 320 is also connected to the gate of the output-stage element T0. The protective circuit 330 is connected to the high-potential-side terminal 102 and the low-potential-side terminal 103. The drain of the output-stage element T0 is connected to the high-potential-side terminal 102, and the source of the output-stage element T0 is connected to an output terminal 105.

The external signal IN1 input via the signal input terminal 101 is a signal for controlling the output-stage element T0. The signal corresponding to the external signal IN1 input via the signal input terminal 101 is input to the drive circuit 320 through the drain of the control circuit element T11 via the logical circuit 310 so as to be converted to a drive signal of the output-stage element T0 in the drive circuit 320. The drive signal of the output-stage element T0 is applied to the gate of the output-stage element T0.

The external signal IN2 input via the signal input terminal 104 is a signal for controlling the protective circuit 330. The signal corresponding to the external signal IN2 input via the signal input terminal 104 is input to the logical circuit 310 through the drain of the control circuit element T12. The logical circuit 310 generates a signal for controlling the protective circuit 330 in accordance with the input signal, so as to control the operation of the protective circuit 330 according to the generated signal.

### Other Embodiments

As described above, the invention has been described according to the first to third embodiments, but it should not be understood that the description and drawings implementing a portion of this disclosure limit the invention. Various alternative embodiments of the present invention, examples, and operational techniques will be apparent to those skilled in the art from this disclosure.

The first and second embodiments have been illustrated above with the case in which the output-stage element T0 is the trench-gate MOS transistor, but are not limited to this case. For example, the output-stage element T0 may be a trench-gate IGBT. When the output-stage element T0 is an IGBT, the n⁺-type low specific resistance layer 11 can be changed to a semiconductor layer of p⁺-type.

The first and second embodiments have been illustrated above with the case in which the semiconductor device (the semiconductor integrated circuit) is the high-side power IC, but may be applied to a semiconductor integrated circuit other than the high-side power IC.

The configurations disclosed in the first to third embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present Specification.

What is claimed is:

1. A semiconductor device comprising:
a semiconductor base body of a first conductivity type;
a high-potential-side terminal connected to the semiconductor base body;
a horizontal first control circuit element deposited at an upper part of the semiconductor base body;
a first signal input terminal connected to a control electrode of the first control circuit element;
a low-potential-side terminal connected to a first main electrode region of the first control circuit element;
an input-side diode connected in a forward direction between the first signal input terminal and the semiconductor base body; and
a vertical protective element connected between the semiconductor base body and the low-potential-side terminal.

2. The semiconductor device of claim 1, further comprising an internal power supply circuit connected between a second main electrode region of the first control circuit element and the high-potential-side terminal.

3. The semiconductor device of claim 1, wherein the vertical protective element is a vertical protective diode connected in a reverse direction between the high-potential-side terminal and the low-potential-side terminal.

4. The semiconductor device of claim 1, wherein the input-side diode includes:
a cathode region that is a part of the semiconductor base body; and
an anode region of a second conductivity type deposited at an upper part of the semiconductor base body.

5. The semiconductor device of claim 3, wherein the vertical protective diode includes:
a cathode region that is a part of the semiconductor base body; and
an anode region of a second conductivity type deposited at an upper part of the semiconductor base body.

6. The semiconductor device of claim 1, wherein the first control circuit element includes:
a well region of a second conductivity type deposited at an upper part of the semiconductor base body;
first and second main electrode regions of the first conductivity type deposited at upper parts of the well region; and
a gate electrode provided on the well region interposed between the first and second main electrode regions via a gate insulating film.

7. The semiconductor device of claim 1, wherein the vertical protective element includes:
a vertical MOS transistor connected between the high-potential-side terminal and the low-potential-side terminal;
a horizontal diode with a cathode connected to the high-potential-side terminal; and,
a resistor connected between an anode of the horizontal diode and the low-potential-side terminal.

8. The semiconductor device of claim 7, wherein the input-side diode includes:
a cathode region that is a part of the semiconductor base body; and
an anode region of a second conductivity type deposited at an upper part of the semiconductor base body.

9. The semiconductor device of claim 7, wherein the vertical MOS transistor includes:
a well region of a second conductivity type deposited at an upper part of the semiconductor base body;
a main electrode region of the first conductivity type deposited at an upper part of the well region; and
a gate electrode buried in a trench via a gate insulating film provided at an upper part of the semiconductor base body.

10. The semiconductor device of claim 7, wherein the horizontal diode is a polysilicon diode provided on the semiconductor base body via an insulating film.

11. The semiconductor device of claim 7, wherein the resistor is a polysilicon resistor provided on the semiconductor base body via an insulating film.

12. The semiconductor device of claim 1, further comprising:
a horizontal second control circuit element deposited at an upper part of the semiconductor base body;
a second signal input terminal connected to a control electrode of the second control circuit element; and
a second input-side diode connected in a forward direction between the second signal input terminal and the high-potential-side terminal.

13. The semiconductor device of claim 1, further comprising a vertical output-stage element provided in the semiconductor base body.
